(19) United States
(12) Patent Application Publication
(10) Pub. No.: US 2016/0205782 A1
(43) Pub. Date: Jul. 14, 2016

(54) PRINTED CIRCUIT BOARD AND METHOD FOR FABRICATING THE SAME

(71) Applicant: NAN YA PCB Corporation, Taoyuan City (TW)

(72) Inventors: Chang-Li HO, Taoyuan City (TW); Ching-Ho SU, Taoyuan City (TW); Willis GAO, Taoyuan City (TW); Chi-Ming LU, Taoyuan City (TW); Cheng-Hung HUANG, Taoyuan City (TW)

(21) Appl. No.: 14/701,264

(22) Filed: Apr. 30, 2015

(30) Foreign Application Priority Data
Jan. 12, 2015 (TW) 104100903

(51) Int. Cl. H05K 1/18; G01R 31/28; H05K 3/34; H05K 3/36; H05K 1/02; H05K 1/11

(52) U.S. Cl. CPC H05K 1/183; H05K 1/0298; H05K 1/111; H05K 1/115; H05K 3/3452; H05K 3/36; G01R 31/2818

(57) ABSTRACT

A printed circuit board is provided, including a products area, an outline area, a plurality of cutting channels, and at least one measurement unit. The products area includes a plurality of circuit board units arranged in a matrix, and each of the circuit board units has a plurality of first internal wiring layers. The outline area surrounds the products area. The cutting channels are located between the outline area and the circuit board units, and between the circuit board units. The measurement unit is disposed in one of the cutting channels and has a plurality of second internal wiring layers and a plurality of contact pads. The second internal wiring layers and the first internal wiring layers are formed by the same fabrication processes. The contact pads are electrically connected to the second internal wiring layers and exposed to a surface of the printed circuit board.

### CROSS REFERENCE TO RELATED APPLICATIONS

The present application claims priority of Taiwan Patent Application No.104100903, filed on Jan. 12, 2015, the entirety of which is incorporated by reference herein.

### BACKGROUND OF THE INVENTION

1. Field of the Invention

The present application relates to an electronic component, and in particular to a printed circuit board and the fabrication method thereof.

2. Description of the Related Art

With the rapid development of electronic technology, electronic products continue to develop toward becoming light, thin, short, small. Therefore, a processing technology of high density interconnection (HDI) for printed circuit boards (PCB) has been used widely, so as to provide more functions in a narrow space and to further reduce total system costs.

In order to monitor the quality and thickness of each internal wiring layer in a printed circuit board, a method which measures the resistance variation of the entire wiring in the printed circuit board is usually used nowadays. However, based on practical experiences, the method cannot precisely reflect the quality and thickness of each internal wiring layer in the printed circuit board, and thus abnormalities in the process cannot also be detected in time. Consequently, the total production yield is still adversely affected. Thus, a printed circuit board and a fabrication method thereof which can overcome the disadvantages described above are needed.

### BRIEF SUMMARY OF THE INVENTION

An embodiment of the invention provides a printed circuit board, including a products area, an outline area, a plurality of cutting channels, and at least one measurement unit. The products area includes a plurality of circuit board units arranged in a matrix, and each of the circuit board units has a plurality of first internal wiring layers. The outline area surrounds the products area. The cutting channels are located between the outline area and the circuit board units, and between the circuit board units. The measurement unit is disposed in one of the cutting channels and has a plurality of second internal wiring layers and a plurality of contact pads. The second internal wiring layers and the first internal wiring layers are formed by the same fabrication processes. The contact pads are electrically connected to the second internal wiring layers and exposed to a surface of the printed circuit board.

Another embodiment of the invention provides a method for fabricating a printed circuit board, including providing a printed circuit board which defines a products area, an outline area, and a plurality of cutting channels. The products area includes a plurality of circuit board units arranged in a matrix, and each of the circuit board units has a plurality of first internal wiring layers. The outline area surrounds the products area. The cutting channels are located between the outline area and the circuit board units, and between the circuit board units. The method also includes forming at least one measurement unit in one of the cutting channels, wherein the measurement unit having a plurality of second internal wiring layers and a plurality of contact pads. The second internal wiring layers and the first internal wiring layers are formed by the same fabrication processes. The contact pads are electrically connected to the second internal wiring layers and exposed to a surface of the printed circuit board.

### BRIEF DESCRIPTION OF THE DRAWINGS

The invention can be more fully understood by reading the subsequent detailed description and examples with references made to the accompanying drawings, wherein:

FIG. 1 is a schematic cross-sectional view for explaining why the measurement of the resistance variation of the entire wiring in a printed circuit board cannot precisely reflect the quality and thickness of each internal wiring layer in the printed circuit board;

FIG. 2 is a partial plan view of a printed circuit board, in accordance with an embodiment of the invention;

FIG. 3 is an enlarged view of part X in FIG. 2;

FIG. 4 is a schematic cross-sectional view taken along the line Y1-Y2 in FIG. 3;

FIG. 5 is a partial plan view of a printed circuit board, in accordance with another embodiment of the invention;

FIG. 6 is a partial plan view of a printed circuit board, in accordance with another embodiment of the invention; and

FIGS. 7A and 7B are schematic cross-sectional views of a solder mask layer and contact pads in a printed circuit board, in accordance with some embodiments of the invention.

### DETAILED DESCRIPTION OF THE INVENTION

In order to illustrate the purposes, features and advantages of the invention, the preferred embodiments and figures of the invention are shown in detail as follows.

Moreover, in the following detailed description, the orientations of “on”, “over”, “above”, “under” and “below” are used for representing the relationship between the relative positions of each element as illustrated in the figures, and are not used to limit the invention.

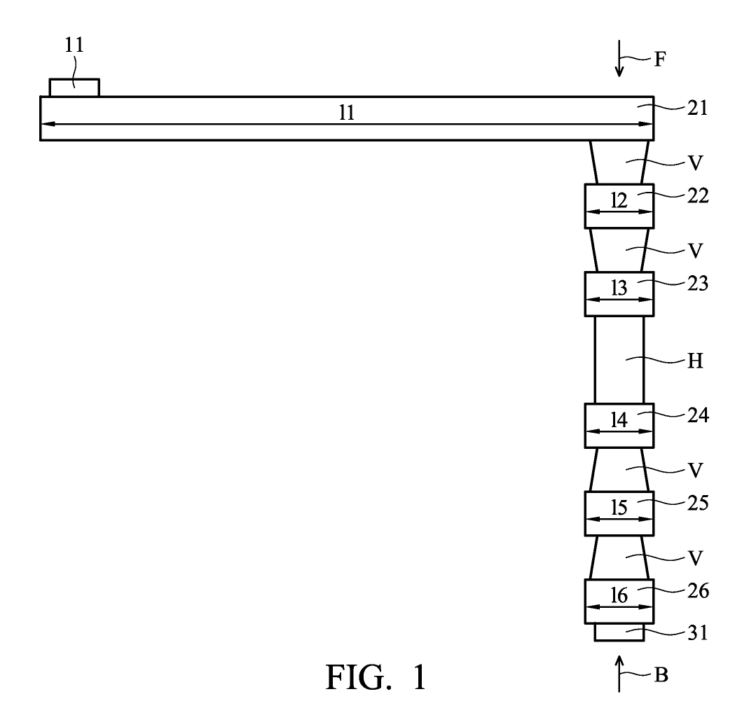

FIG. 1 is a schematic cross-sectional view for explaining why the measurement of the resistance variation of the entire wiring in a printed circuit board cannot precisely reflect the quality and thickness of each internal wiring layer in the printed circuit board. As shown in FIG. 1, a contact pad 11 and another contact pad 31 are respectively located on an upper surface F and a lower surface B of the printed circuit board. Moreover, the contact pads 11 and 31 are electrically connected to each other by a plurality of internal wiring layers 21˜26, a plurality of conductive via holes V, and a conductive plated through hole (PTH) H. It should be understood that some dielectric layers, such as resin material layers, between the internal wiring layers 21˜26 are omitted in FIG. 1. The material and fabrication method of the contact pads 11 and 31, the internal wiring layers 21˜26, the conductive via holes V, and the conductive plated through hole H are a known technology in this field, and thus are not described here.

While the widths and thicknesses of the internal wiring layers 21˜26 are supposed to be consistent, the resistance of the entire wiring in FIG. 1 is determined by the total length. However, because of the high density interconnection (HDI) design, the lengths 11, 12, 13, 14, 15, and 16 of the internal wiring layers 21˜26 are so much shorter relative to the total length of the entire wiring, i.e. the sum of 11 to 16. Therefore, the resistance variation of each of the internal wiring layers 21˜26, and abnormalities in the process of each of the internal wiring layers 21˜26 cannot be precisely detected by merely measuring the resistance variation of the entire wiring in the printed circuit board.

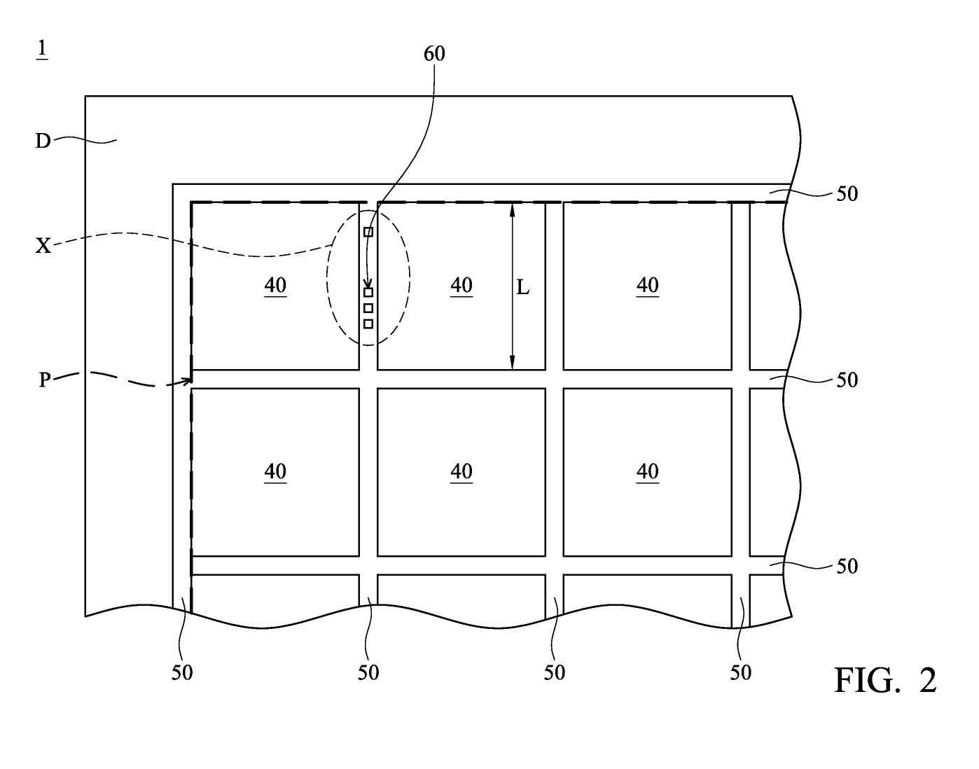

FIG. 2 is a partial plan view of a printed circuit board, in accordance with an embodiment of the invention. As shown in FIG. 2, the printed circuit board 1 of this embodiment primarily includes a products area P, an outline area D, a plurality of cutting channels 50, and at least one measurement unit 60 (e.g. a plurality of measurement units 60 (FIG. 2 only shows one of them)).

The products area P includes a plurality of circuit board units 40 arranged in a matrix, and each of the circuit board units 40 has the internal wiring design shown in FIG. 1, i.e. they all have a plurality of internal wiring layers 21˜26. The outline area D (also known as dummy area) surrounds the products area P, and is not used for arrangement of the circuit board units 40. The cutting channels 50, extended along the horizontal or vertical direction, are located between the products area P (the circuit board units 40) and the outline area D, and between the circuit board units 40.

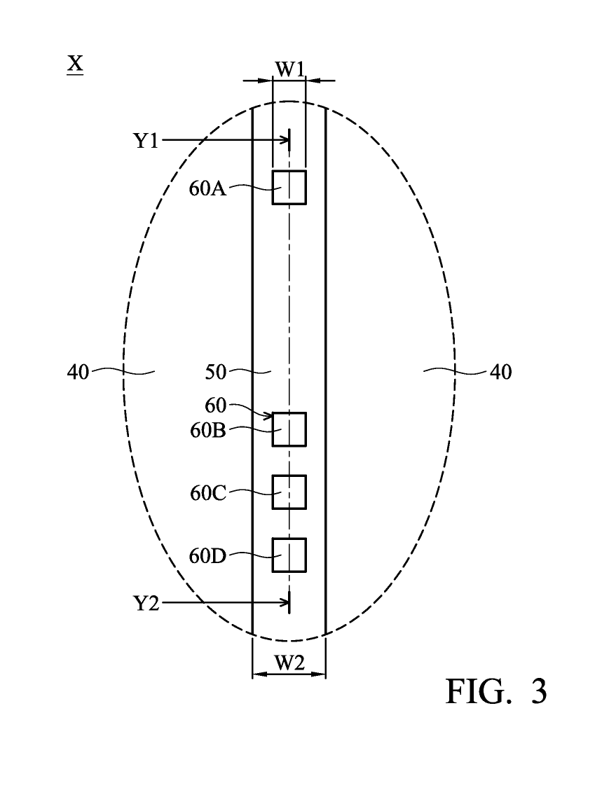

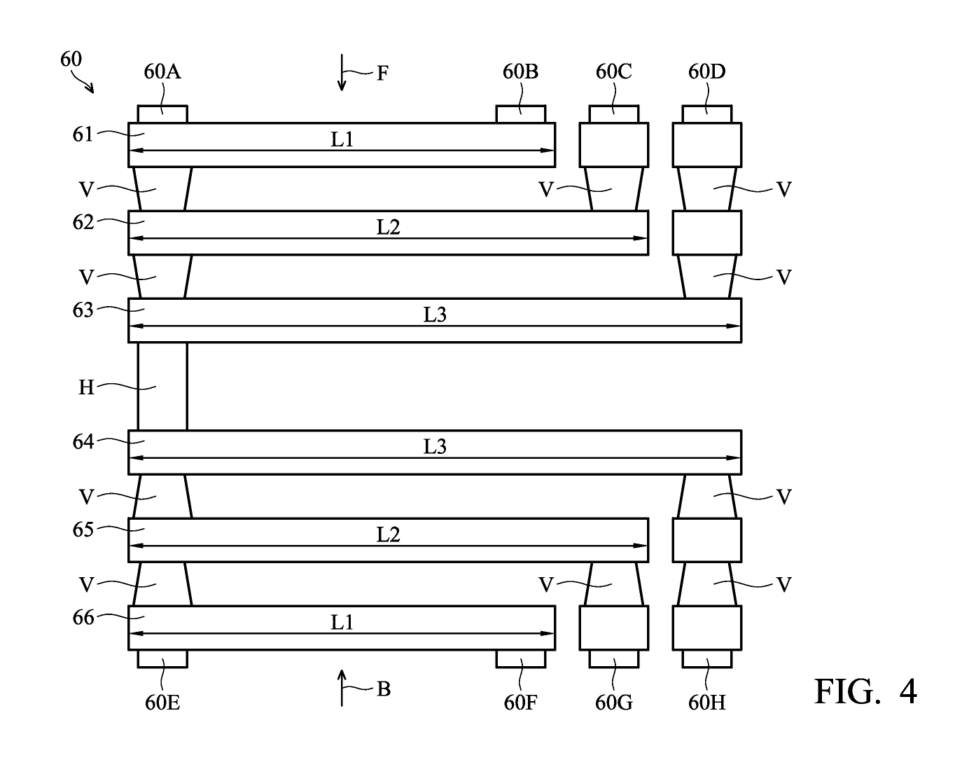

Next, referring to FIGS. 2 to 4, wherein FIG. 3 is an enlarged view of part X in FIG. 2, and FIG. 4 is a schematic cross-sectional view taken along the line Y1-Y2 in FIG. 3. In this embodiment, the measurement unit 60 is disposed in the cutting channel 50 between two adjacent circuit board units 40. Moreover, the measurement unit 60 has a plurality of internal wiring layers 61˜66, a plurality of conductive via holes V and a conductive plated through hole H that are electrically connected to the internal wiring layers 61˜66, a plurality of contact pads 60A˜60D exposed to the upper surface F of the printed circuit board 1, and a plurality of contact pads 60E˜60H exposed to the lower surface B of the printed circuit board 1. It should be understood that some dielectric layers, such as resin material layers, between the internal wiring layers 61˜66 are also omitted in FIG. 4.

Furthermore, the measurement unit 60 is disposed in the cutting channel 50 in a manner substantially parallel thereto. Specifically, the internal wiring layers 61˜63 are substantially extended along a longitudinal axis of the cutting channel 50. The contact pads 60A˜60D are disposed on the longitudinal axis and electrically connected to the internal wiring layers 61˜63. Note that the internal wiring layers 64˜66 and contact pads 60E˜60H are symmetrical to the internal wiring layers 61˜63 and the contact pads 60A˜60D. That is, the internal wiring layers 64˜66 are also substantially extended along the longitudinal axis of the cutting channel 50, and the contact pads 60E˜60H are disposed on the longitudinal axis and electrically connected to the internal wiring layers 64˜66. As shown in FIG. 3, the measurement unit 60 of this embodiment is substantially arranged on the center line of the cutting channel 50, and the width W1 (first width) of the measurement unit 60 may be smaller than or equal to the width W2 (second width) of the cutting channel 50.

Although the internal wiring layers 61˜66 of this embodiment are substantially extended along a longitudinal axis of the cutting channel 50, in some embodiments, the internal wiring layers 61˜66 may also be extended along the longitudinal axis of the cutting channel 50 in a staggered manner, as long as the quality of the circuit board units 40 is not adversely affected.

Furthermore, the internal wiring layers 61˜66 (second internal wiring layers) correspond to the internal wiring layers 21˜26 (first internal wiring layers) of the circuit board units 40. More specifically, the internal wiring layers 61˜66 and the internal wiring layers 21˜26 are formed by the same fabrication processes and have the same material and thickness.

As shown in FIG. 4, the contact pads 60A and 60B are electrically connected to both ends of the internal wiring layer 61, the contact pads 60A and 60C are electrically connected to both ends of the internal wiring layer 62, and the contact pads 60A and 60D are electrically connected to both ends of the internal wiring layer 63. Similarly, the contact pads 60E˜60H are also electrically connected to both ends of each of the internal wiring layers 64˜66. Specifically, the lengths L1, L2, and L3 of the internal wiring layers 61˜66 may be shorter than or equal to the length of the longitudinal axis of the cutting channel 50, and the lengths L1˜L3 are determined by the actual requirement. Preferably, the lengths L1˜L3 are between one-third to two-thirds of a side length L of the circuit board units 40 (FIG. 2).

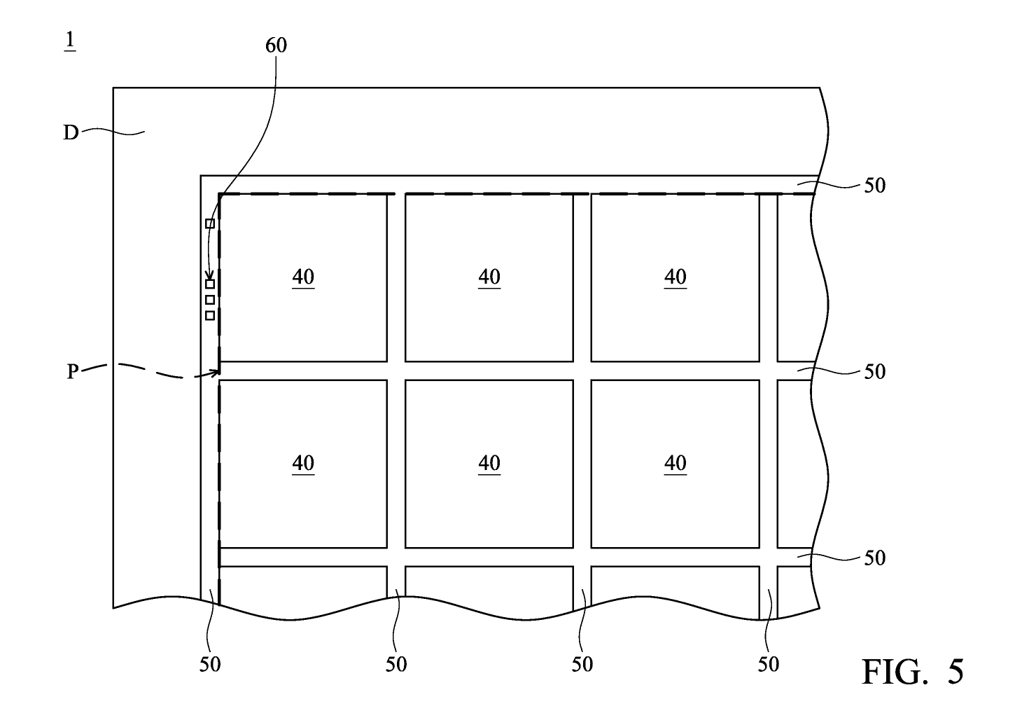

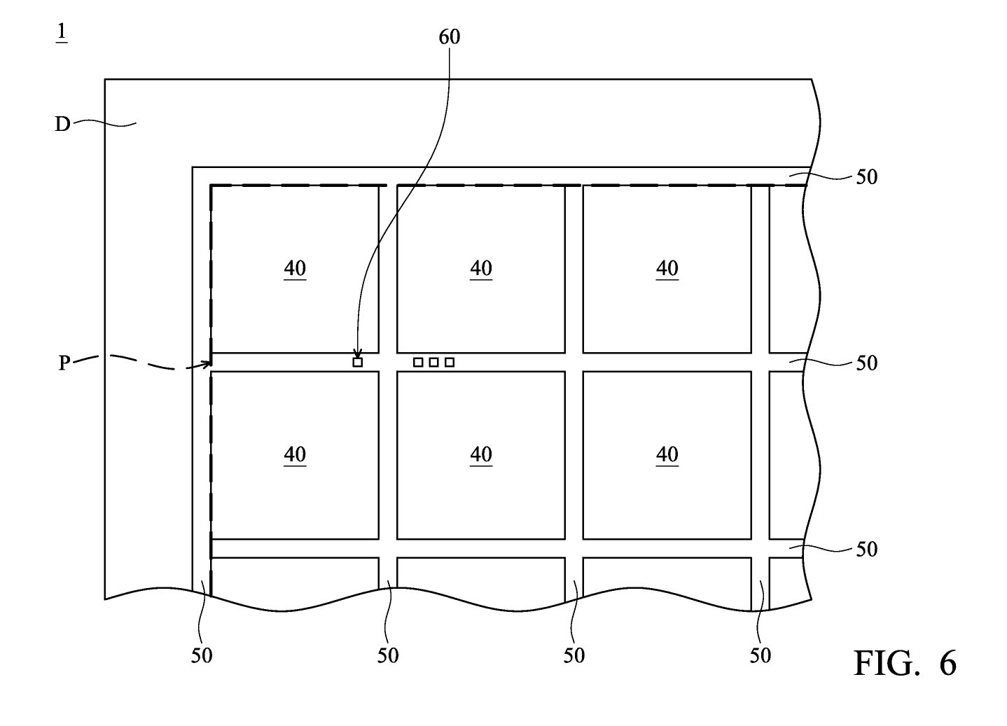

FIGS. 5 and 6 are partial plan views of a printed circuit board, in accordance with some other embodiments of the invention. The difference between the printed circuit boards in FIGS. 5 and 6 and the printed circuit board in FIG. 2 is the arranged location of the measurement unit 60. As shown in FIG. 5, the measurement unit 60 may be disposed in the cutting channel 50 between the circuit board units 40 and the outline area D (adjacent to a side of the circuit board units 40). As shown in FIG. 6, the measurement unit 60 may be disposed at the intersection of two cutting channels 50 and adjacent to four circuit board units 40.

With the above structural designs, each of the internal wiring layers 61˜66 (second internal wiring layers) of the measurement unit 60 has enough length so that the quality and thickness variations thereof can be precisely detected by measuring the resistance variation of each of the internal wiring layers 61˜66. Moreover, the measurement unit 60 is disposed in the cutting channel 50 near the circuit board units 40, therefore quality and thickness variations of the internal wiring layers 21˜26 (first internal wiring layers) of the circuit board units 40 (either one or several of them, and even a part or the whole thereof) can be effectively detected by monitoring the resistance variation of the internal wiring layers 61˜66 (second internal wiring layers) of the measurement unit 60. Furthermore, quality and thickness variations of the internal wiring layers of the circuit board units 40 are detected before cutting the cutting channels 50 to get the circuit board units 40, such that abnormalities in the process can be detected in time. Thus, the total production yield of the printed circuit board 1 is improved.

It should be realized that the structure of the measurement unit 60 is not limited to the above embodiments and may be designed according to the actual requirement. For example, while the number or material of the dielectric layers and the internal wiring layers in the circuit board units 40 of the printed circuit board 1 are changed, the number or material of the dielectric layers and the internal wiring layers in the measurement unit 60 can also be changed accordingly. In some embodiments, the contact pads of the measurement unit 60 may also be disposed on the same surface of the printed circuit board.

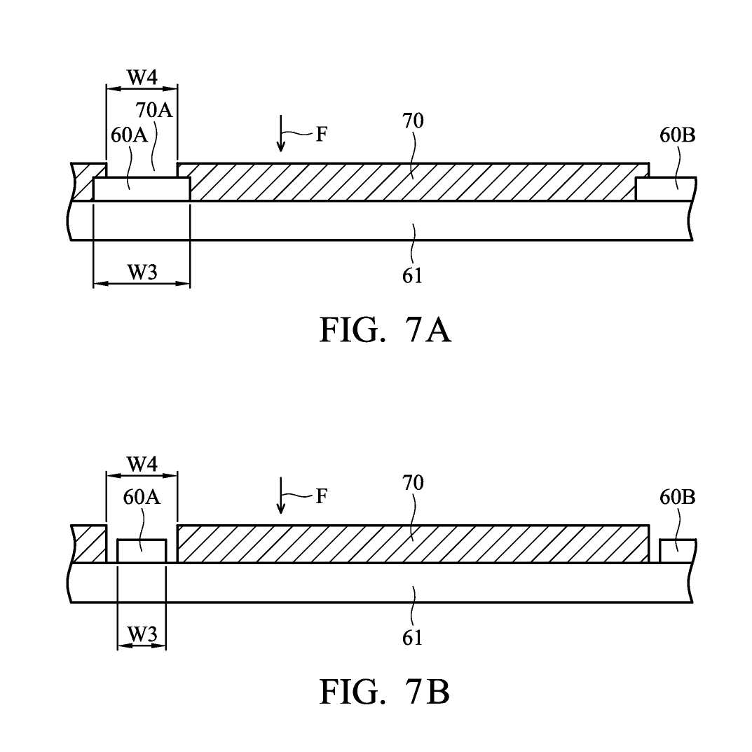

FIGS. 7A and 7B are schematic cross-sectional views of a solder mask layer and contact pads in a printed circuit board, in accordance with some embodiments of the invention. As shown in FIGS. 7A and 7B, the printed circuit board further includes a solder mask layer 70 covering the upper surface F for protecting the internal wiring layers 61˜66 (the internal wiring layers 62˜66 are not shown). Moreover, the solder mask layer 70 has a plurality of openings 70A which correspond to the contact pads 60A˜60D (the contact pads 60C and 60D are not shown), wherein the widths W4 (third width) of the openings 70A may be smaller than, equal to, or larger than the widths W3 (fourth width) of the contact pads 60A˜60D. Similarly, the printed circuit board may also include another solder mask layer on the lower surface B thereof (FIG. 4). The material and fabrication method of the solder mask layer are also a known technology in this field, and thus are not described here.

As described above, the invention provides a printed circuit board, including a products area, an outline area, a plurality of cutting channels, and at least one measurement unit. The products area includes a plurality of circuit board units arranged in a matrix, and each of the circuit board units has a plurality of first internal wiring layers. The outline area surrounds the products area. The cutting channels are located between the outline area and the circuit board units, and between the circuit board units. The measurement unit is disposed in one of the cutting channels and has a plurality of second internal wiring layers and a plurality of contact pads. The second internal wiring layers and the first internal wiring layers are formed by the same fabrication processes. The contact pads are electrically connected to the second internal wiring layers and exposed to a surface of the printed circuit board.

Furthermore, the invention also provides a method for fabricating a printed circuit board, including providing a printed circuit board which defines a products area, an outline area, and a plurality of cutting channels. The products area includes a plurality of circuit board units arranged in a matrix, and each of the circuit board units has a plurality of first internal wiring layers. The outline area surrounds the products area. The cutting channels are located between the outline area and the circuit board units, and between the circuit board units. The method also includes forming at least one measurement unit in one of the cutting channels, wherein the measurement unit having a plurality of second internal wiring layers and a plurality of contact pads. The second internal wiring layers and the first internal wiring layers are formed by the same fabrication processes. The contact pads are electrically connected to the second internal wiring layers and exposed to a surface of the printed circuit board.

With the structural features in the above disclosed embodiments of the invention, quality and thickness variations of the internal wiring layers of the circuit board units in the products area can be detected by monitoring the resistance variation of the internal wiring layers of the measurement unit near the circuit board units. Moreover, the measurement unit is disposed in the cutting channels and thus will not occupy the products area of the printed circuit board. Furthermore, quality and thickness variations of the internal wiring layers of the circuit board units are detected before cutting the cutting channels to get the circuit board units, such that abnormities in the process can be detected in time. Consequently, the total production yield of the printed circuit board can be effectively improved.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A printed circuit board, comprising:
a products area, including a plurality of circuit board units arranged in a matrix, wherein each of the circuit board units has a plurality of first internal wiring layers;
an outline area, surrounding the products area;
a plurality of cutting channels, located between the outline area and the circuit board units, and between the circuit board units; and
at least one measurement unit, disposed in one of the cutting channels, having:
a plurality of second internal wiring layers, wherein the second internal wiring layers and the first internal wiring layers are formed by the same fabrication processes; and
a plurality of contact pads, electrically connected to the second internal wiring layers and exposed to a surface of the printed circuit board.

2. The printed circuit board as claimed in claim 1, wherein the measurement unit is disposed in the cutting channel in a manner substantially parallel thereto.

3. The printed circuit board as claimed in claim 2, wherein the second internal wiring layers are substantially extended along a longitudinal axis of the cutting channel.

4. The printed circuit board as claimed in claim 3, wherein the second internal wiring layers have lengths that are shorter than or equal to another length of the longitudinal axis of the cutting channel.

5. The printed circuit board as claimed in claim 1, wherein the measurement unit is disposed between two adjacent circuit board units or disposed on a side thereof.

6. The printed circuit board as claimed in claim 1, wherein a first width of the measurement unit is smaller than or equal to a second width of the cutting channel.

7. The printed circuit board as claimed in claim 1, further comprising a solder mask layer, covering the surface of the printed circuit board and having a plurality of openings which correspond to the contact pads.

8. The printed circuit board as claimed in claim 7, wherein a third width of the openings is larger than a fourth width of the contact pads.

9. A method for fabricating a printed circuit board, comprising:
providing a printed circuit board which defines a products area, an outline area, and a plurality of cutting channels, wherein the products area includes a plurality of circuit board units arranged in a matrix, each of the circuit board units having a plurality of first internal wiring layers, the outline area surrounds the products area, and the cutting channels are located between the outline area and the circuit board units, and between the circuit board units; and
forming at least one measurement unit in one of the cutting channels, the measurement unit having a plurality of second internal wiring layers and a plurality of contact pads, wherein the second internal wiring layers and the first internal wiring layers are formed by the same fabrication processes, and the contact pads are electrically connected to the second internal wiring layers and exposed to a surface of the printed circuit board.

10. The method for fabricating a printed circuit board as claimed in claim 9, wherein the measurement unit is disposed in the cutting channel in a manner substantially parallel thereto.

11. The method for fabricating a printed circuit board as claimed in claim 10, wherein the second internal wiring layers are substantially extended along a longitudinal axis of the cutting channel.

12. The method for fabricating a printed circuit board as claimed in claim 11, wherein the second internal wiring layers have lengths that are shorter than or equal to another length of the longitudinal axis of the cutting channel.

13. The method for fabricating a printed circuit board as claimed in claim 9, wherein the measurement unit is disposed between two adjacent circuit board units or disposed on a side thereof.

14. The method for fabricating a printed circuit board as claimed in claim 9, wherein a first width of the measurement unit is smaller than or equal to a second width of the cutting channel.

15. The method for fabricating a printed circuit board as claimed in claim 9, further comprising:
forming a solder mask layer on the surface of the printed circuit board, wherein the solder mask layer has a plurality of openings which correspond to the contact pads.

16. The method for fabricating a printed circuit board as claimed in claim 15, wherein a third width of the openings is larger than a fourth width of the contact pads.
